(19) United States
(12) Patent Application Publication
(10) Pub. No.: US 2026/0334214 A1
(43) Pub. Date: Oct. 22, 2026

(54) INTEGRATED CIRCUIT AND METHOD OF DESIGNING THE INTEGRATED CIRCUIT

(71) Applicant: Samsung Electronics Co., Ltd., Suwon-si (KR)

(72) Inventors: Wook Kim, Suwon-si (KR); Sunggu Kang, Suwon-si (KR)

(21) Appl. No.: 19/574,679

(22) Filed: Mar. 23, 2026

(30) Foreign Application Priority Data
Apr. 17, 2025 (KR) 10-2025-0050412

(51) Int. Cl. H10W 20/40; H10W 20/20

(52) U.S. Cl. CPC H10W 20/481; H10W 20/2134; H10W 20/496

(57) ABSTRACT

An integrated circuit includes a first back-end-of-line (BEOL) region including a back-side power delivery network (BSPDN, a front-end-of-line (FEOL) region including a plurality of transistors, a second BEOL region including signal patterns configured to apply signals to the plurality of transistors, and a bonding layer in contact with one surface of the second BEOL region, wherein the integrated circuit includes a plurality of cells including a first cell, and the first cell includes at least one through via connected to the FEOL region.

### CROSS-REFERENCE TO RELATED APPLICATION

This application is based on and claims priority under 35 U.S.C. § 119 to Korean Patent

Application No. 10-2025-0050412, filed on Apr. 17, 2025, in the Korean Intellectual Property Office, the disclosure of which is incorporated by reference herein in its entirety.

### BACKGROUND

Integrated circuits processing a digital signal may include standard cells, and each of the standard cells may have a unique function and structure. Due to the development of semiconductor processes, the size of the standard cells may be reduced, and accordingly, routing for supplying power to the standard cells may not be easy. To this end, integrated circuits with a back-side power delivery network (BSPDN) structure that supplies power from the back-side are emerging. The BSPDN structure that supplies power from the back-side is formed by a bulkless process. In this regard, it is difficult to solve a reliability problem caused by heat generated inside compared to a structure that supplies power from the front-side.

### SUMMARY

The present disclosure relates to an integrated circuit and a method of designing the integrated circuit, and more particularly, to an integrated circuit including a temperature control cell and a method of designing the integrated circuit.

Aspects of the present disclosure provide an integrated circuit with a structure that facilitates heat dissipation and effectively controls temperature.

According to an aspect of the present disclosure, there is provided an integrated circuit comprising a back-side power delivery network (BSPDN).

The integrated circuit includes a first back-end-of-line (BEOL) region comprising the BSPDN; a front-end-of-line (FEOL) region comprising a plurality of transistors; a second BEOL region comprising signal patterns configured to apply signals to the plurality of transistors; a bonding layer in contact with a first surface of the second BEOL region; and wherein the integrated circuit comprises a plurality of cells including a first cell, wherein the first cell comprises at least one through via connected to the FEOL region.

According to an aspect of the present disclosure, there is provided an integrated circuit.

The integrated circuit includes a plurality of standard cells; and a plurality of filler cells comprising a first cell, wherein the first cell cells comprises a through via configured to dissipate heat generated in a front-end-of-line (FEOL) region, and wherein the through via is in at least one of a first BEOL region below the FEOL region or a second BEOL region above the FEOL region.

According to an aspect of the present disclosure, there is provided an integrated circuit.

The integrated circuit includes a plurality of standard cells comprising a first cell; and a plurality of filler cells, wherein the first cell comprises a through via configured to dissipate heat generated in a front-end-of-line (FEOL) region, and wherein the through via is in at least one of a first BEOL region below the FEOL region or a second BEOL region above the FEOL region.

The through via may be in contact with a transistor included in the FEOL region.

### BRIEF DESCRIPTION OF THE DRAWINGS

Implementations will be more clearly understood from the following detailed description taken in conjunction with the accompanying drawings in which:

FIG. 1 is a plan view illustrating a layout of an integrated circuit according to an implementation;

FIG. 2 is a plan view illustrating a layout of an integrated circuit according to an implementation;

FIGS. 3A and 3B are cross-sectional views of integrated circuits according to an implementation;

FIGS. 4A and 4B are cross-sectional views of a temperature control cell included in an integrated circuit according to an implementation;

FIG. 4C is a plan view illustrating an example of a temperature control cell included in an integrated circuit;

FIG. 4D is a cross-sectional view of the temperature control cell of FIG. 4C taken along line A-A′;

FIG. 5 is a cross-sectional view of a standard cell according to an implementation;

FIGS. 6A, 6B, and 6C are cross-sectional views of temperature control cells according to an implementation;

FIG. 6D is a plan view of a bonding layer according to an implementation;

FIGS. 7A, 7B, and 7C are cross-sectional views of temperature control cells according to an implementation;

FIG. 7D is a cross-sectional view of a first back-end-of-line (BEOL) region where a plurality of metal-insulator-metal (MIM) capacitors are formed according to an implementation;

FIGS. 8A and 8B are cross-sectional views of temperature control cells according to an implementation;

FIG. 9 is a flowchart illustrating a method of placing and routing temperature control cells, according to an implementation;

FIGS. 10A, 10B, 10C, and 10D are diagrams for explaining a process of placing and routing temperature control cells according to an implementation;

FIG. 11 is a flowchart illustrating a method of manufacturing an integrated circuit, according to an implementation;

FIGS. 12A, 12B, 12C, and 12D are diagrams illustrating examples of devices according to implementations;

FIG. 13 is a block diagram illustrating a system-on-chip according to an implementation; and

FIG. 14 is a block diagram illustrating a computing system including a memory storing a program according to an implementation.

### DETAILED DESCRIPTION

Hereinafter, various implementations are described with reference to the accompanying drawings.

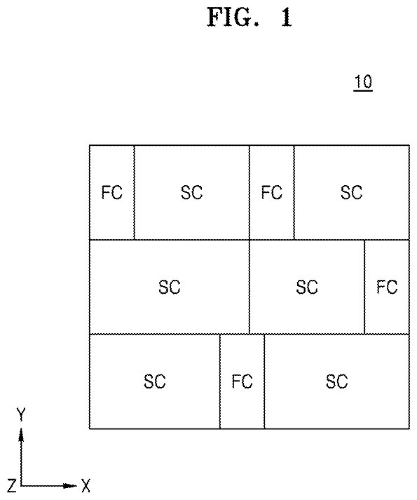

FIG. 1 is a plan view illustrating a layout of an integrated circuit 10 according to an implementation.

FIG. 1 is a plan view illustrating the layout of the integrated circuit 10 viewed in the −Z axis direction. Herein, each of the X-axis direction and the Y-axis direction may be referred to as a horizontal direction, and the Z-axis direction may be referred to as a vertical direction. A plane formed by the X-axis and the Y-axis may be referred to as a horizontal plane, a component positioned in a +Z-axis direction relative to other components may be referred to as being above other components, and a component positioned in a −Z-axis direction relative to other components may be referred to as being below other components. In some implementations, the area of a component may refer to the size of the component in a plane parallel to a horizontal plane, and a width of the component may refer to a length in a direction orthogonal to a direction in which the component extends. A surface exposed in the +Z direction may be referred to as a top surface, a surface exposed in the −Z direction may be referred to as a bottom surface, and a surface exposed in the ±X direction or the ±Y direction may be referred to as a side surface. For convenience of illustration, only some layers may be shown in the drawings, and a via connecting an upper pattern to a lower pattern may be displayed in the upper pattern for understanding even though the via is located below the upper pattern. In some implementations, a pattern including a conductive material, such as a pattern of a wiring layer, may be referred to as a conductive pattern or simply referred to as a pattern.

The integrated circuit 10 of FIG. 1 may include a plurality of cells therein. The cell may receive an input signal and generate an output signal. The cell may include an input pin for receiving the input signal, and may include an output pin for outputting the output signal.

Referring to FIG. 1, the integrated circuit 10 may include a plurality of standard cells SC and a plurality of filler cells FC adjacent to the plurality of standard cells SC. The plurality of standard cells SC may be defined as a circuit region, and the plurality of filler cells FC may be defined as a dummy region. The standard cell SC, which is a unit of layout included in an integrated circuit, may be designed to perform a predefined function. The standard cell SC may comply with a predetermined rule and may have a predefined height.

The integrated circuit 10 of FIG. 1 includes six standard cells SC and four filler cells FC, but the present disclosure may include standard cells SC and filler cells FC arranged in more various forms.

According to an implementation, the filler cell FC included in the integrated circuit 10 may be a temperature control filler cell configured to perform a temperature control function. FIG. 1 illustrates an example in which all of the filler cells FC included in the integrated circuit 10 are temperature control filler cells, but the present disclosure is not limited thereto, and only some of the filler cells FC included in the integrated circuit 10 may be temperature control filler cells. Hereinafter, for convenience of description, the filler cell FC and the temperature control filler cell may be described interchangeably.

According to an implementation, the integrated circuit 10 may easily control the temperature of the integrated circuit 10 by arranging the filler cell FC disposed in a dummy region as the temperature control filler cell. According to an example, when a reliability issue occurs due to excessive heat generated in the standard cell SC included in the integrated circuit 10, a path through which heat generated from the standard cell SC may be easily dissipated through connection of an adjacent temperature control filler cell to the standard cell SC may be secured. A detailed structure of the temperature control filler cell is described below with reference to the following drawings.

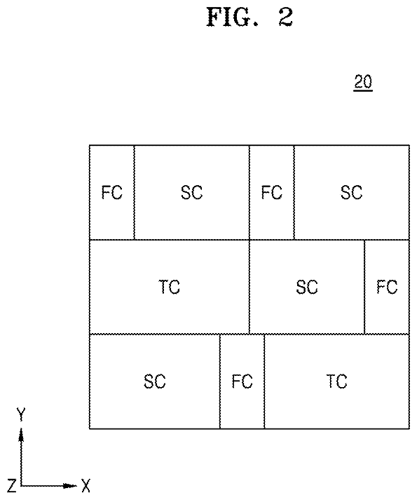

FIG. 2 is a plan view illustrating a layout of an integrated circuit 20 according to an implementation.

The integrated circuit 20 of FIG. 2 may include a plurality of cells therein. The integrated circuit 20 of FIG. 2 may include a plurality of standard cells SC, a plurality of temperature control standard cells TC, and a plurality of filler cells FC. In the integrated circuit 20 of FIG. 2, descriptions of configurations redundant with the descriptions of the integrated circuit 10 of FIG. 1 are omitted.

According to an example, the integrated circuit 20 may further include the plurality of temperature control standard cells TC. The temperature control standard cell TC may be a cell configured to additionally perform a temperature control function while including the same logic circuit as the standard cell SC. According to an implementation, when temperature control is required in a region where the standard cell SC is disposed, the integrated circuit 20 may easily process temperature control in the corresponding region by arranging the temperature control standard cell TC at the corresponding position.

The integrated circuits 10 and 20 of FIGS. 1 and 2 may include the filler cell FC performing the temperature control function and/or the temperature control standard cell TC in addition to the standard cell SC, thereby easily dissipating heat generated from active devices included in the integrated circuits 10 and 20. According to the present disclosure, a cell itself can have a function of enabling temperature control, thereby easily enabling temperature control simply by arranging the cell at a position where an electro migration (EM) problem may occur. Hereinafter, the filler cell FC performing the temperature control function and the temperature control standard cell TC are collectively referred to as a temperature control cell.

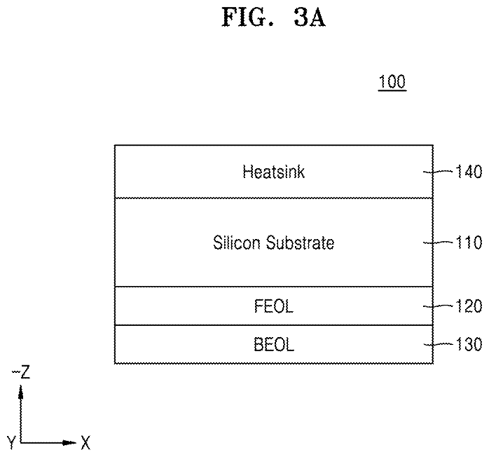

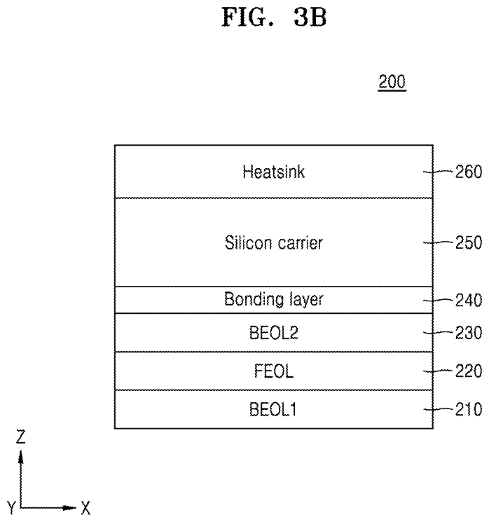

FIGS. 3A and 3B are cross-sectional views of integrated circuits 100 and 200 according to an implementation.

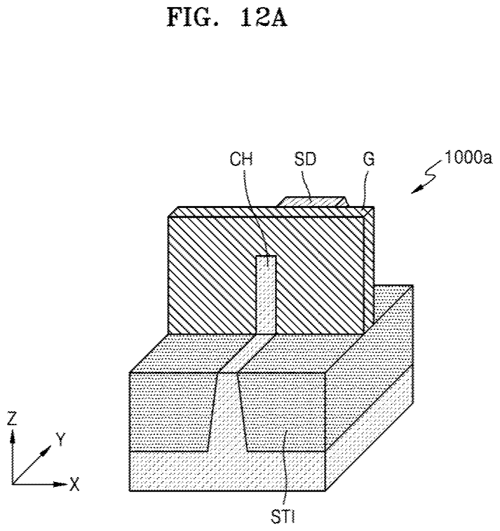

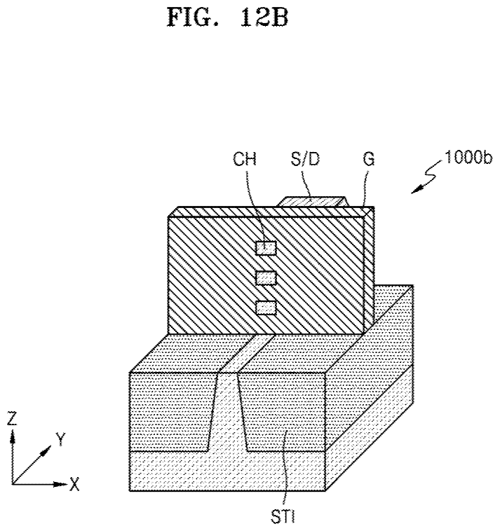

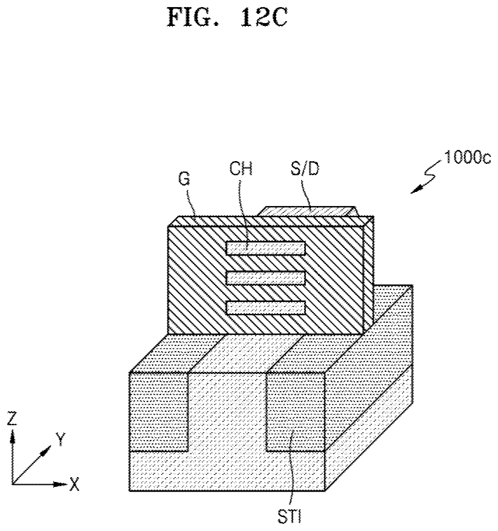

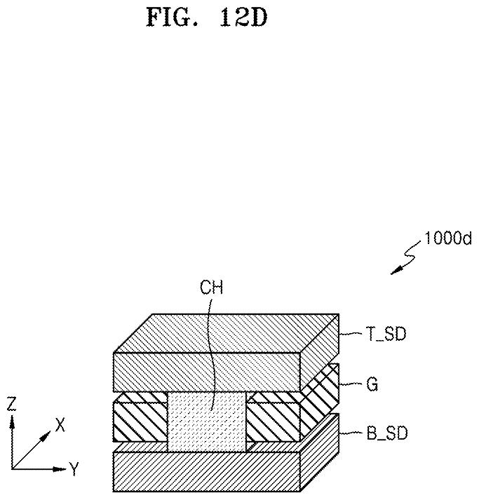

The integrated circuit 100 of FIG. 3A may include a substrate 110, a front-end-of-line (FEOL) region 120, a back-end-of-line (BEOL) region 130, and a heat sink 140. According to an implementation, active devices, such as transistors, may be formed in the FEOL region 120, and examples of the formed devices are described below with reference to FIGS. 12A to 12D. The BEOL region 130 may be formed in the +Z-axis direction of the FEOL region 120, and the BEOL region 130 may include patterns including a conductive material. For example, the BEOL region 130 may include patterns for input signals and/or output signals of devices (referred to as signal patterns herein) and patterns for supplying power to devices (referred to as power patterns herein). In some implementations, the patterns formed on the BEOL region 130 may include metal. The BEOL region 130 of the integrated circuit 100 may include a plurality of wiring layers, and patterns respectively formed in adjacent wiring layers may be electrically interconnected to each other through vias. In some implementations, a supply voltage, such as a positive supply voltage and/or a negative supply voltage (or ground potential), may be applied to power patterns of the BEOL region 130.

For example, the devices may receive a supply voltage applied to a pad on the plurality of wiring layers through the patterns respectively formed on the plurality of wiring layers. As described above, a structure in which the supply voltage is provided from the +Z axis direction of the substrate 110 may be referred to as a front-side power delivery network (FSPDN). In some implementations, the power patterns may be regularly disposed in the BEOL region 130 so that power is stably supplied to the devices, and signal patterns may be disposed in a region where no power pattern is disposed in the BEOL region 130.

According to an example, the heat sink 140 may be disposed to contact one surface of the substrate 110. For example, the heat sink 140 may dissipate heat generated from the FEOL region 120 to the outside of the integrated circuit 100. The heat sink 140 may include a material having high thermal conductivity. The heat sink 140 may include at least one of copper (Cu), nickel (Ni), or gold (Au), but the present disclosure is not limited thereto. As in the implementation of FIG. 3A, in the case of the FSPDN structure, heat generated by the transistors of the FEOL region 120 may be easily removed through the substrate 110 including silicon and the heat sink 140.

The integrated circuit 200 of FIG. 3B may include a first BEOL region 210, a FEOL region 220, a second BEOL region 230, a bonding layer 240, a silicon carrier 250, and a heat sink 260. According to an implementation, active devices, such as transistors, may be formed in the FEOL region 220, and examples of the formed devices are described below with reference to FIGS. 12A to 12D. According to an example, the FEOL region 220 may include components necessary for configuring a logic cell. For example, the FEOL region 220 may include a plurality of active regions, a plurality of source/drain regions, a plurality of gate lines, and a plurality of wiring structures for selectively interconnecting or externally connecting the plurality of active regions, the plurality of source/drain regions, and the plurality of gate lines.

The first BEOL region 210 may be located below the FEOL region 220, and the second BEOL region 230 may be located above the FEOL region 220. According to an example, the first BEOL region 210 may be referred to as a back-side wiring layer, and the second BEOL region 230 may be referred to as a front-side wiring layer. According to an example, power patterns may be included in the first BEOL region 210, and signal patterns may be included in the second BEOL region 230. According to an example, in order to supply power to a device from the power patterns formed on the back-side wiring layer, the integrated circuit 200 may include a through-silicon via (TSV). The TSV may be connected to the power pattern of the first BEOL region 210, and may be connected to the transistor formed in the FEOL region 220. Accordingly, the supply voltage may be provided to the devices through the TSV from the power pattern formed on the first BEOL region 210, which is the back-side wiring layer. As described above, a structure in which the supply voltage is provided in the −Z axis direction of the FEOL region 220 may be referred to as a back-side power delivery network (BSPDN).

The integrated circuit 200 having the BSPDN structure according to an example may further include the bonding layer 240 on an upper portion of the second BEOL region 230. The bonding layer 240 may include a silicon oxide layer, a silicon nitride layer, a silicon carbide layer, or a combination thereof, but is not limited thereto. The silicon carrier 250, which may be a bulk silicon wafer, may be disposed in the upper portion of the bonding layer 240, and the heat sink 260 may be disposed in an upper portion of the silicon carrier 250.

In the integrated circuit 200 with the BSPDN structure, a path for dissipating heat generated in the FEOL region 220 may be formed in a direction of the silicon carrier 250 through the second BEOL region 230 and the bonding layer 240. However, because the bonding layer 240 includes the oxide layer and has a very low thermal conductivity compared to silicon, it might be difficult to easily dissipate the heat generated in the FEOL region 220.

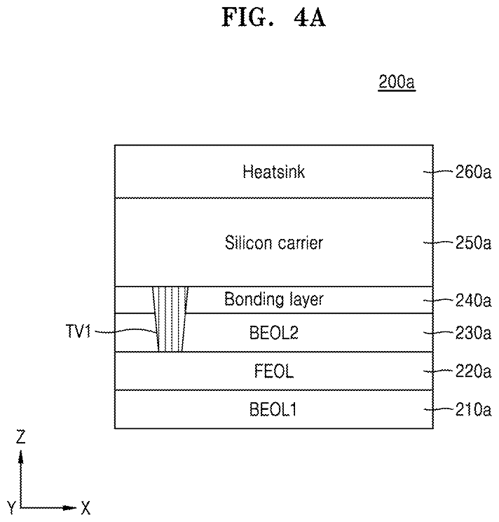

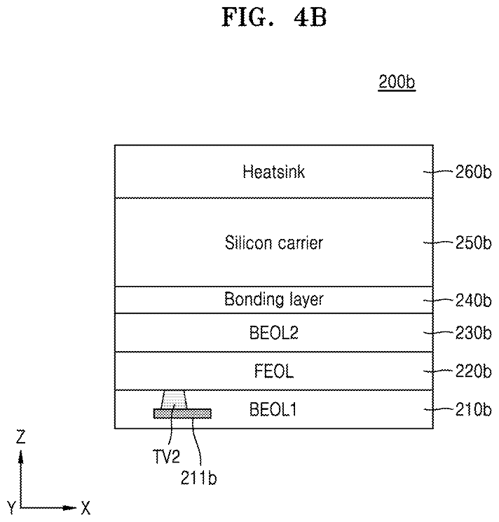

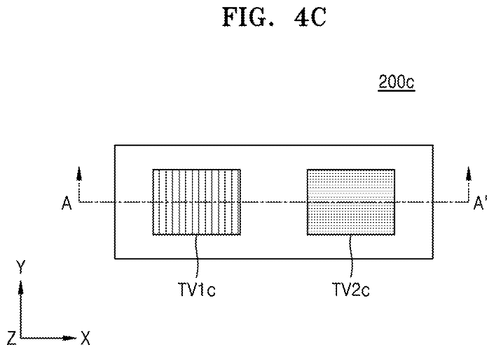

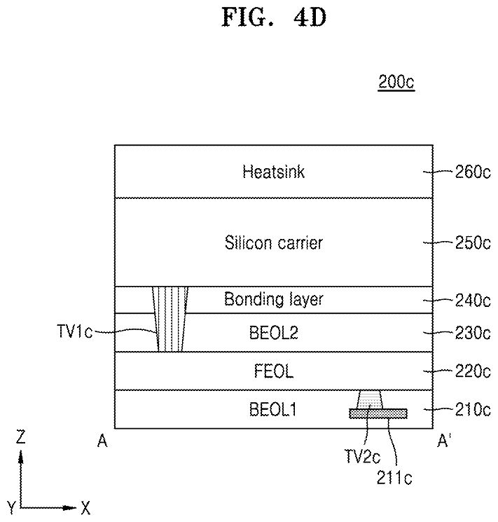

FIGS. 4A and 4B are cross-sectional views of a temperature control cell included in an integrated circuit 200a according to an implementation.

Referring to FIG. 4A, the integrated circuit 200a may include a first BEOL region 210a, an FEOL region 220a, a second BEOL region 230a, a bonding layer 240a, a silicon carrier 250a, and a heat sink 260a. The integrated circuit 200a of FIG. 4A corresponds mostly to the configuration of the integrated circuit 200 of FIG. 3B, and thus descriptions of redundant configurations are omitted.

According to an example, the integrated circuit 200a may further include a first through via TV1. The first through via TV1 may be formed to penetrate the bonding layer 240a and the second BEOL region 230a. According to an example, the first through via TV1 may be a TSV. The first through via TV1 may penetrate the bonding layer 240a so that one surface of the first through via TSV1 may be in contact with the silicon carrier 250a. The first through via TV1 may penetrate the second BEOL region 230a so that one surface of the first through via TSV1 may be in contact with the FEOL region 220a. According to an example, the first through via TV1 may have a cylindrical shape with an empty inside. In some implementations, a distance between both ends of the first through via TV1 may be the same as a distance from a bottom surface of the silicon carrier 250a to a top surface of the FEOL region 220a.

As described above, the integrated circuit 200a may include the first through via TV1, and thus a dissipation path of heat generated in the FEOL region 220a may be formed in an upward direction toward the silicon carrier 250a. In some implementations, the integrated circuit 200a may use a structure that penetrates the bonding layer 240a with low thermal conductivity, and thus the integrated circuit 200a with a BSPDN structure may easily perform heat dissipation.

Referring to FIG. 4B, the integrated circuit 200b may include a first BEOL region 210b, an FEOL region 220b, a second BEOL region 230b, a bonding layer 240b, a silicon carrier 250b, and a heat sink 260b. The integrated circuit 200b of FIG. 4B corresponds mostly to the configuration of the integrated circuit 200 of FIG. 3B, and thus descriptions of redundant configurations are omitted.

The integrated circuit 200b may further include a second through via TV2. The second through via TV2 may be formed to penetrate a partial depth of the first BEOL region 210b. According to an example, the second through via TV2 may be connected to a metal plate 211b formed in the first BEOL region 210b. According to an example, the metal plate 211b may be an upper metal plate included in a metal-insulator-metal (MIM) capacitor. According to an implementation, the first BEOL region 210b of the integrated circuit 200b may include a plurality of MIM capacitors for securing capacitance and dissipating heat, and among the plurality of MIM capacitors, the upper metal plate 211b of the MIM capacitor connected to the second through via TV2 may be utilized as a heat sink and a lower path for dissipating heat generated in the FEOL region 220b.

FIG. 4C is a plan view illustrating an example of a temperature control cell 200c included in an integrated circuit.

The temperature control cell 200c of FIG. 4C may include a first through via TV1c and a second through via TV2c. Unlike FIGS. 4A and 4B, the temperature control cell 200c included in the integrated circuit may include both the first through via TV1c and the second through via TV2c. According to an implementation, the first through via TV1c and the second through via TV2c may be aligned and disposed in the X-axis direction, but arrangement positions of the first through via TV1c and the second through via TV2c may not be limited thereto.

In some implementations, the temperature control cell 200c includes one first through via TV1c and one second through via TV2c, but the number of first through vias TV1c and second through vias TV2c that may be included in one temperature control cell 200c may not be limited as shown.

FIG. 4D is a cross-sectional view of the temperature control cell 200c of FIG. 4C taken along line A-A′.

Referring to FIG. 4D, the temperature control cell 200c may include a first BEOL region 210c, an FEOL region 220c, a second BEOL region 230c, a bonding layer 240c, a silicon carrier 250c, and a heat sink 260c. Referring to FIG. 4D, the temperature control cell 200c may include the first through via TV1c penetrating the bonding layer 240c and the second BEOL region 230c, and the second through via TV2c penetrating a part of the first BEOL region 210c. The second through via TV2c may be in contact with a metal plate 211c formed in the first BEOL region 210c.

As described above, the temperature control cell 200c includes the first through via TV1c and the second through via TV2c connected to the FEOL region 220c, and thus heat generated from a plurality of transistor devices in the FEOL region 220c may be diffused to paths in both directions, i.e., an upper path and a lower path, thereby easily processing dissipation of heat generated from the temperature control cell 200c.

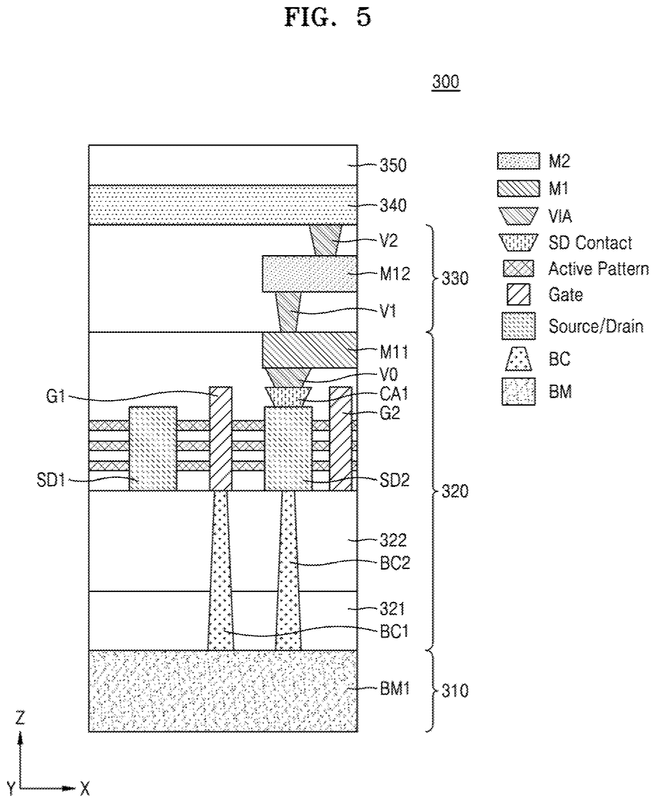

FIG. 5 is a cross-sectional view of a standard cell 300 according to an implementation. According to an example, the standard cell 300 of FIG. 5 may be an example of the standard cell SC of FIG. 1.

According to an example, the standard cell 300 may include a first BEOL region 310, a FEOL region 320, a second BEOL region 330, a bonding layer 340, and a heat sink 350.

According to an example, the FEOL region 320 may include gate electrodes G1 and G2 extending in the Y-axis direction, and include active regions 322 extending in the X-axis direction. According to an example, the active region 322 may be a p-channel field effect transistor (PFET) region or an n-channel field effect transistor (NFET) region. At least one active pattern may extend in the X-axis direction in the active region 322, and be combined with the gate electrodes G1 and G2 to form a transistor. For example, as shown in FIG. 5, three active patterns may extend in the X-axis direction in the active region 322, and form FETs with the gate electrodes G1 and G2.

Sources/drains may be disposed at both sides of the gate electrodes G1 and G2, and source/drain contacts SD Contacts may be disposed on the sources/drains. For example, as shown in FIG. 5, a first source/drain SD1 and a second source/drain SD2 may be disposed on both sides of the second gate electrode G1. Channels may be formed between the sources/drains below the gate electrodes G1 and G2. A via of a first via layer V0 may be disposed on the source/drain contact SD Contact, and connected to the source/drain contact SD Contact and a pattern M11 of a first wiring layer M1. For example, as shown in FIG. 5, a source/drain contact CA1 may be disposed on a second source/drain SD2, and the first via layer V0 connected to the pattern M11 of the first wiring layer M1 may be disposed on the source/drain contact CA1.

In some implementations, a gate contact may be formed on a gate electrode, and connected to a source/drain contact. In some implementations, the gate contact may be directly connected to the pattern M11 of the first wiring layer M1. Herein, the source/drain contact and the gate contact may be referred to as front-side contacts, or simply referred to as contacts.

According to an example, the second BEOL region 330 may include a signal pattern M12 connecting signals and a plurality of vias V1 and V2.

The first BEOL region 310 of the standard cell 300 may include patterns BM extending from a back-side wiring layer below a substrate 321 of the FEOL region 320. For example, as shown in FIG. 5, a first back-side pattern BM1 may extend below the substrate 321 in the X-axis direction in a back-side metal layer. In some implementations, the substrate 321 may include an insulating layer such as a nitride based back-side interlayer dielectric (ILD) extending in a horizontal direction to insulate the active regions 322 and the back-side wiring layer from each other.

The standard cell 300 may include a back-side contact penetrating the substrate 321 in a vertical direction. For example, as shown in FIG. 5, a first back-side contact BC1 may have a bottom surface connected to the first back-side pattern BM1 and a top surface connected to the first gate electrode G1. A second back-side contact BC2 may have a bottom surface connected to the first back-side pattern BM1 and a top surface connected to the second source/drain SD2. In some implementations, the back-side contact may penetrate active patterns or a source/drain and be connected to a source/drain contact.

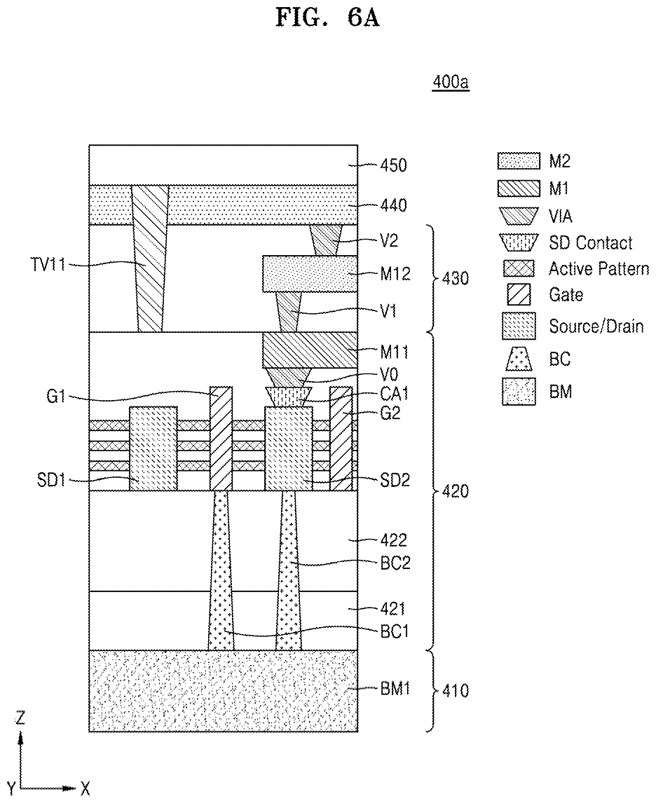

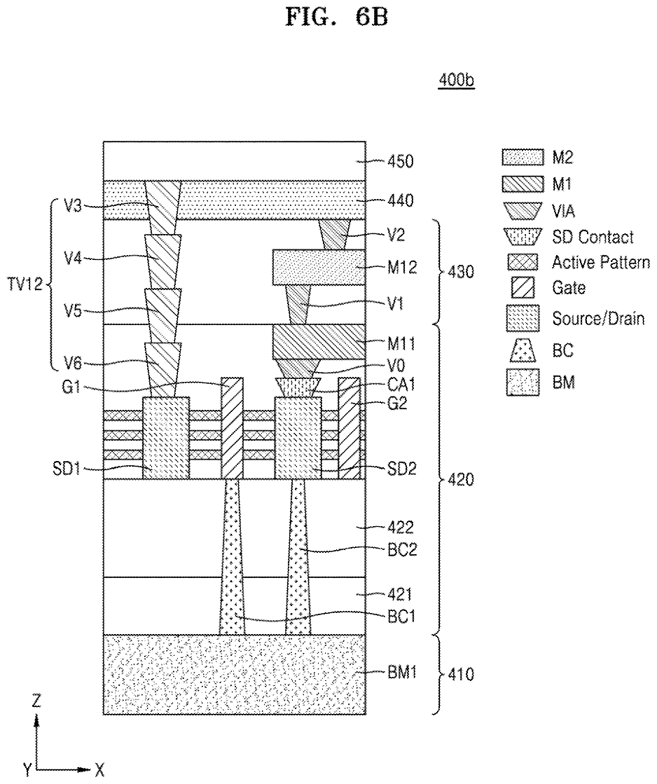

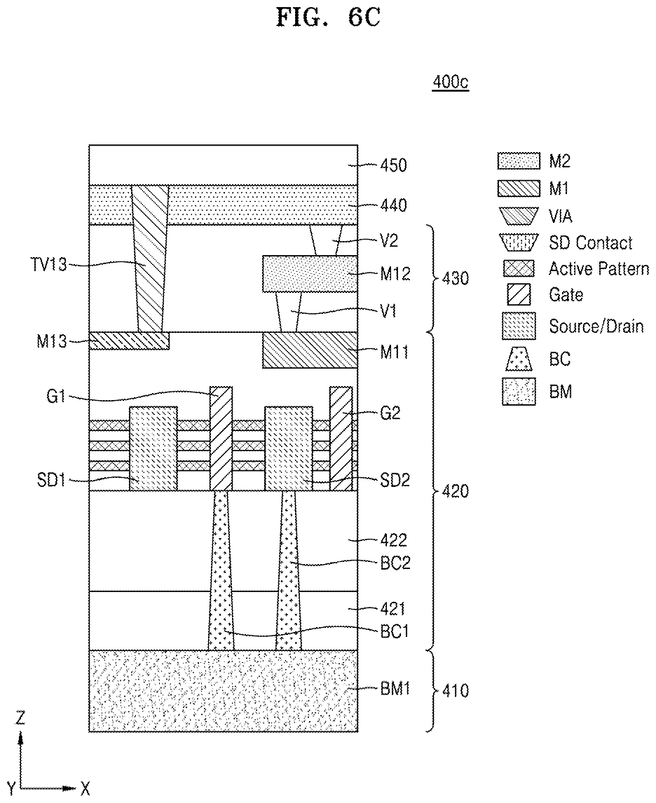

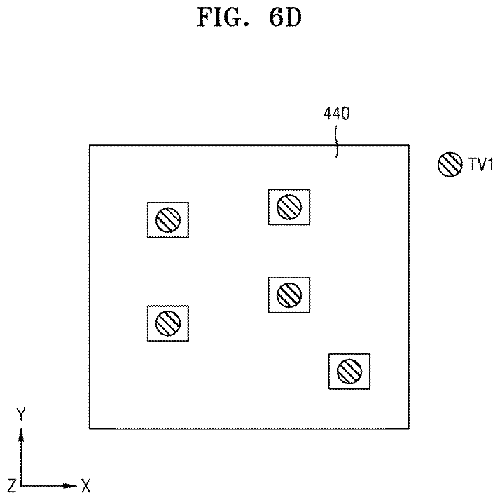

FIGS. 6A to 6C are cross-sectional views of temperature control cells 400a, 400b, and 400c according to an implementation. The temperature control cells 400a and 400b of FIGS. 6A and 6B may be examples of the temperature control standard cell TC of FIG. 2. The temperature control cell 400c of FIG. 6C may be an example of the temperature control filler cell FC of FIGS. 1 and 2.

The temperature control cells 400a, 400b, and 400c of FIGS. 6A to 6C each may include a first BEOL region 410, a FEOL region 420, a second BEOL region 430, a bonding layer 440, and a silicon carrier 450. According to an example, components of the first BEOL region 410, the FEOL region 420, the second BEOL region 430, the bonding layer 440 and the silicon carrier 450 respectively correspond to components of the first BEOL region 310, the FEOL region 320, the second BEOL region 330, the bonding layer 340, and the silicon carrier 350 of FIG. 5, and thus, descriptions of redundant components are omitted.

Referring to FIG. 6A, the temperature control cell 400a may include a first through via TV11. The first through via TV11 may be provided in a TSV structure penetrating the second BEOL region 430 and the bonding layer 440. One end of the first through via TV11 may be in contact with one end of the silicon carrier 450, and the other end of the first through via TV11 may be in contact with one end of the FEOL region 420.

Referring to FIG. 6B, the temperature control cell 400b may include a first through via structure TV12. The first through via structure TV12 may be provided in a stacked via structure. The first through via structure TV12 may include a plurality of vias V3, V4, V5, and V6 that are stacked. According to an example, the first through via structure TV12 may penetrate the bonding layer 440 and the second BEOL region 430, and may penetrate a part of the FEOL region 420. Among the plurality of vias V3, V4, V5, and V6 included in the first through via structure TV12, the lowermost via V6 may be in contact with the first source/drain region SD1 formed in the FEOL region 420. According to an example, the first through via structure TV12 may be directly connected to a transistor formed in the FEOL region 420. As described above, the first through via structure TV12 may be directly connected to the transistor, thereby increasing the efficiency of heat dissipation. According to an example, the structure of the first through via structure TV12 is applied to a temperature control standard cell, but it should be noted that the structure of the first through via structure TV12 may also be applied to a temperature control filler cell.

Referring to FIG. 6C, the temperature control cell 400c may include a first through via TV13. According to an example, active devices of the FEOL region 420 included in the temperature control cell 400c may be dummy transistors. No contact may be formed in the first and second gate electrodes G1 and G2 and the first and second source/drain regions SD1 and SD2 included in the FEOL region 420, and the temperature control cell 400c including the dummy transistors may easily perform heat dissipation through the first through via TV13 while functioning as a dummy filler cell. According to an example, the first through via TV13 may be connected to a metal layer M13 formed in the FEOL region 420. According to an example, when the temperature control cell 400c is a filler cell, it is highly likely that the temperature control cell 400c is used as a path for dissipating heat generated from an adjacent standard cell rather than dissipating heat generated inside the temperature control cell 400c. According to an implementation, the temperature control cell 400c may be electrically connected to a transistor of the adjacent standard cell through the metal layer M13 formed in the FEOL region 420 to be used as a dissipation path of heat in an FEOL region of the adjacent standard cell. According to an example, the metal layer M13 connected to the first through via TV13 may be formed on the silicon carrier 450. According to an example, when a standard cell adjacent to the temperature control cell 400c is disposed at a position determined to be a problem area as a result of EM analysis to be described below, the temperature control cell 400c may be electrically connected to the standard cell through the metal layer M13 to be used as a path for dissipating heat from the standard cell.

FIG. 6D is a plan view of the bonding layer 440 according to an implementation. According to an implementation, a plurality of first through vias TV1 penetrating the bonding layer 440 may be formed. The plurality of first through vias TV1 may not be aligned, may be formed at various positions where heat is generated, and the number of first through vias TV1 may not be limited.

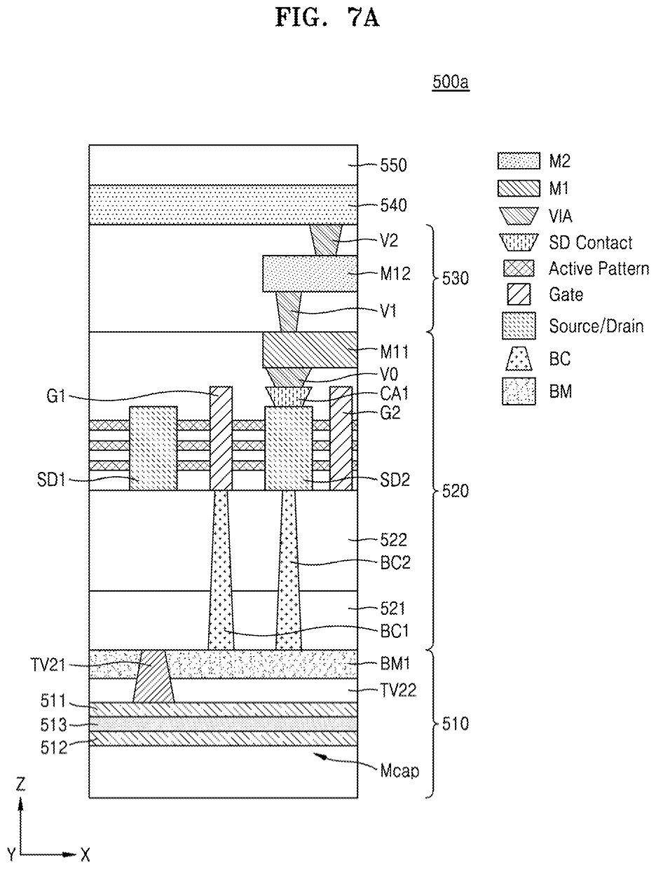

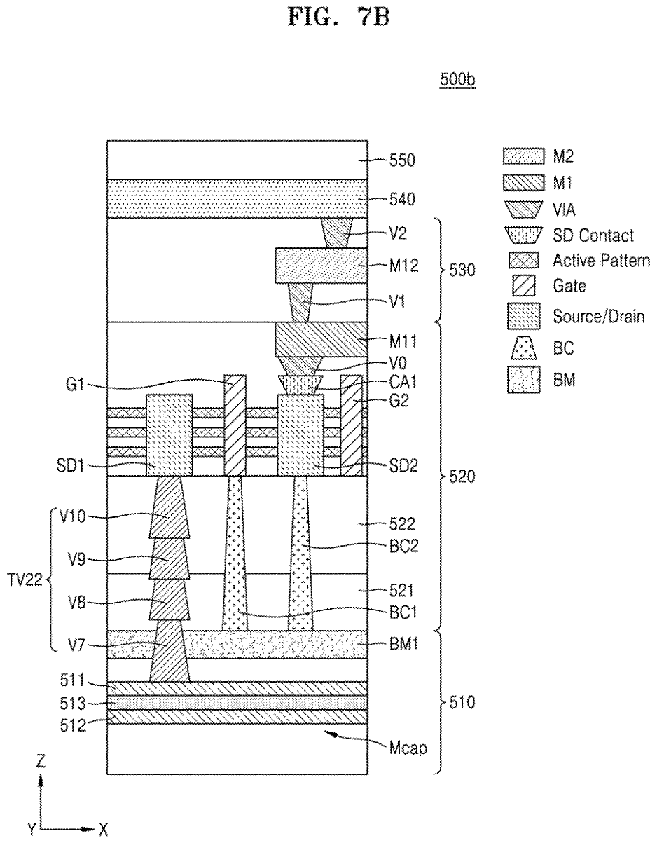

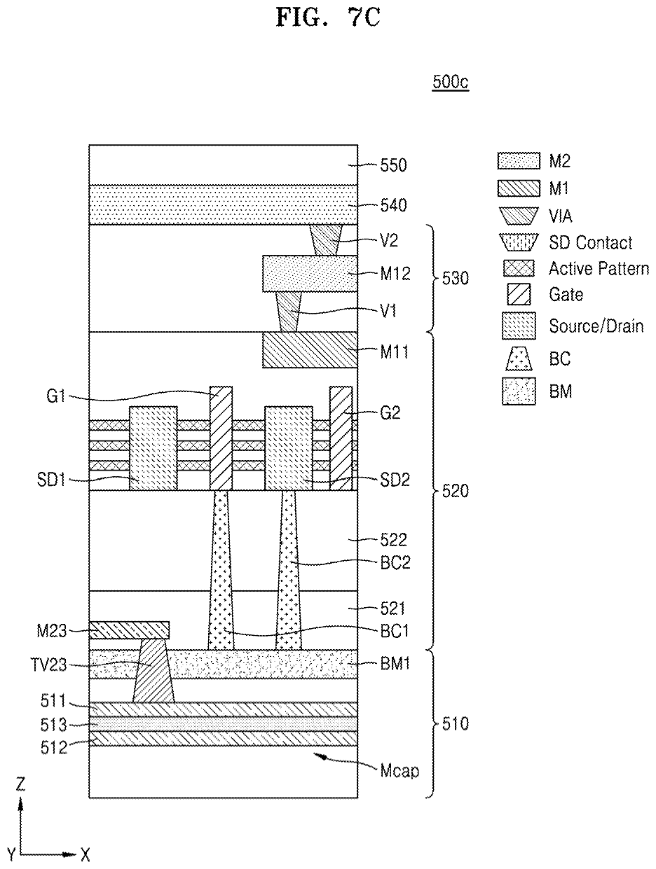

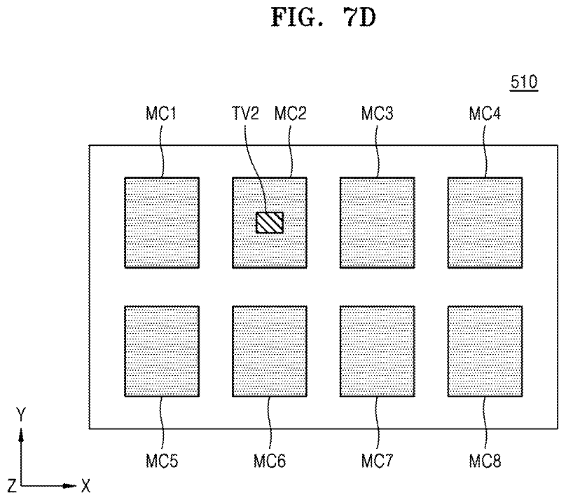

FIGS. 7A to 7C are cross-sectional views of temperature control cells 500a, 500b, and 500c according to an implementation. The temperature control cells 500a and 500b of FIGS. 7A and 7B may be examples of the temperature control standard cell TC of FIG. 2. The temperature controlling cell 500c of FIG. 7C may be an example of the temperature controlling filler cell FC of FIGS. 1 and 2.

The temperature control cells 500a, 500b, and 500c of FIGS. 7A to 7C may include a first BEOL region 510, a FEOL region 520, a second BEOL region 530, a bonding layer 540, and a silicon carrier 550. According to an implementation, components of the first BEOL region 510, the FEOL region 520, the second BEOL region 530, the bonding layer 540, and the silicon carrier 550 respectively correspond to components of the first BEOL region 310, the FEOL region 320, the second BEOL region 330, the bonding layer 340, and the silicon carrier 350 of FIG. 5, and thus, descriptions of redundant components are omitted.

Referring to FIG. 7A, the first BEOL region 510 of the temperature control cell 500a may include a second through via TV21. The second through via TV21 may be formed to penetrate the first back-side pattern BM1 of the first BEOL region 510. The second through via TV21 may be in contact with a bottom surface of a substrate 521 of the FEOL region 520. The first BEOL region 510 may include an MIM capacitor Mcap. The MIM capacitor Mcap may include a first metal plate 511 and a second metal plate 512 which are spaced apart from each other in the Z-axis direction and extend in the X-axis direction, and an insulating plate 513 disposed between the first metal plate 511 and the second metal plate 512. According to an example, one surface of the second through via TV21 may be in contact with the first metal plate 511. According to an implementation, the second through via TV21 may be connected to the FEOL region 520 to be utilized as a path for transferring heat generated in the FEOL region 520 to the first metal plate 511.

Referring to FIG. 7B, the first BEOL region 510 of the temperature control cell 500b may include a second through via structure TV22. The second through via structure TV22 may be provided in a stacked via structure. The second through via structure TV22 may include a plurality of vias V7, V8, V9, and V10 that are stacked. The second through via structure TV22 may penetrate a partial depth of the first BEOL region 510, and may penetrate a partial depth of the FEOL region 520. According to an example, among the plurality of vias V7, V8, V9, and V10 included in the second through via structure TV22, the uppermost via V10 may contact the first source/drain region SD1 formed in the FEOL region 520. According to an example, the second through via structure TV22 may be directly connected to a transistor formed in the FEOL region 520. As such, the second through via structure TV22 may be directly connected to the transistor, thereby increasing the efficiency of heat dissipation. According to an example, the structure of the second through via structure TV22 is applied to a temperature control standard cell, but it should be noted that the structure of the second through via structure TV22 may also be applied to a temperature control filler cell.

Referring to FIG. 7C, the temperature control cell 500c may include a second through via TV23. According to an implementation, active devices of the FEOL region 520 included in the temperature control cell 500c may be dummy transistors. No contact may be formed in the first and second gate electrodes G1 and G2 and the first and second source/drain regions SD1 and SD2 included in the FEOL region 520, and the temperature control cell 500c including the dummy transistors may perform temperature control through the second through via TV23 while functioning as a dummy filler cell. According to an implementation, the second through via TV23 may be connected to a metal layer M23 formed in the FEOL region 520. According to an example, when the temperature control cell 500c is a filler cell, it is highly likely that the temperature control cell 500c is used as a path for dissipating heat generated from an adjacent standard cell rather than dissipating heat generated inside the temperature control cell 500c. According to an implementation, the temperature control cell 500c may be electrically connected to a transistor of the adjacent standard cell through the metal layer M23 formed in the FEOL region 520 to be used as a dissipation path of heat in an FEOL region of the adjacent standard cell. According to an example, when a standard cell adjacent to the temperature control cell 500c is a cell disposed at a position determined to be a problem area as a result of EM analysis to be described below, the temperature control cell 500c may be electrically connected to the standard cell through the metal layer M23 to be used as a path for dissipating heat from the standard cell.

FIG. 7D is a cross-sectional view of the BEOL region 510 in which a plurality of MIM capacitors MC1, MC2, MC3, MC4, MC5, MC6, MC7, and MC8 are formed according to an implementation.

In the implementation of the temperature control cells 500a, 500b, and 500c of FIGS. 7A to 7C, the MIM capacitor Mcap is illustrated as one capacitor extending in the X-axis direction, but a plurality of MIM capacitors Mcap may be spaced apart from each other on an X-Y-axis plane as shown in FIG. 7D. FIG. 7D is a cross-sectional view of the entire BEOL region 510 including a plurality of standard cells and filler cells. The first BEOL region 510 may include the plurality of MIM capacitors MC1, MC2, MC3, MC4, MC5, MC6, MC7, and MC8, which are spaced apart from each other.

According to an example, the second through via TV2 may be formed at a position where a lot of heat is generated in the entire region of an integrated circuit, and a metal plate of the MIM capacitor MC2 disposed at the corresponding position in the Z-axis direction may be connected to the second through via TV2. In the implementation of FIG. 7D, the MIM capacitor MC2 connected to the second through via TV2 among the plurality of MIM capacitors MC1, MC2, MC3, MC4, MC5, MC6, MC7, and MC8 may be used as a heat sink, and the other MIM capacitors MC1, MC3, MC4, MC5, MC6, MC7, and MC8 may be used to secure capacitance.

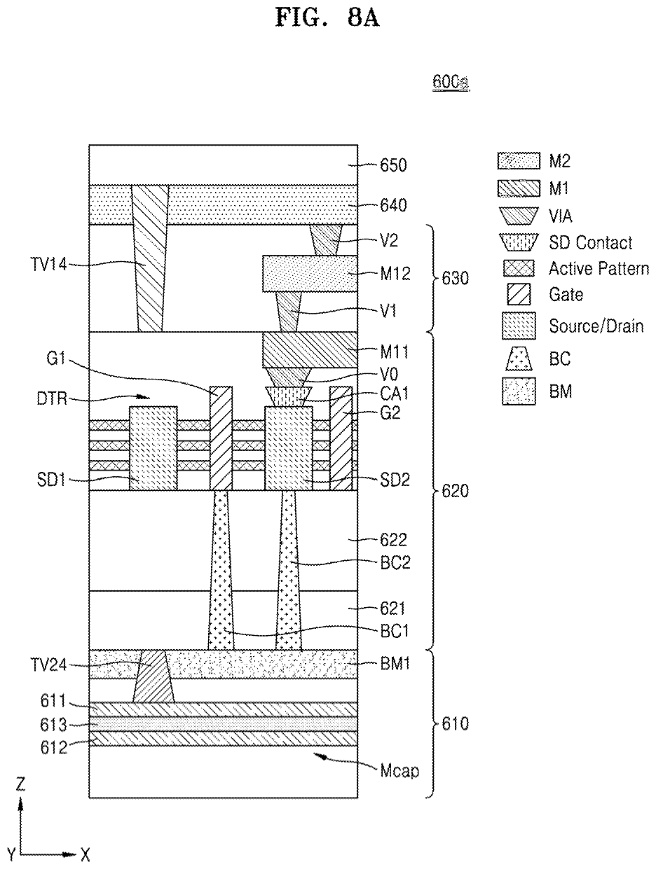

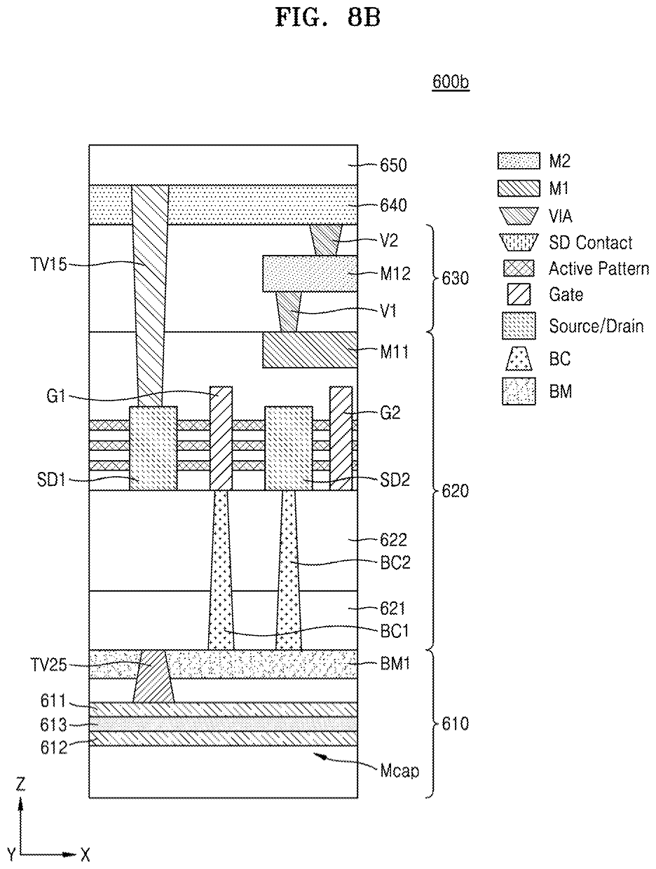

FIGS. 8A and 8B are cross-sectional views of temperature control cells 600a and 600b according to an implementation. The temperature control cell 600a of FIG. 8A may be an example of the temperature control standard cell TC of FIG. 2. The temperature control cell 600b of FIG. 8B may be an example of the temperature control filler cell FC of FIGS. 1 and 2.

Referring to FIGS. 8A and 8B, each of the temperature control cells 600a and 600b may include a first BEOL region 610, a FEOL region 620, a second BEOL region 630, a bonding layer 640, and a silicon carrier 650. Components of the first BEOL region 610, the FEOL region 620, the second BEOL region 630, the bonding layer 640, and the silicon carrier 650 according to an implementation respectively correspond to the components of the first BEOL region 310, the FEOL region 320, the second BEOL region 330, the bonding layer 340, and the silicon carrier 350 of FIG. 5, and thus descriptions of redundant components are omitted.

According to an example, the temperature control cell 600a may include a first through via TV14 and a second through via TV24. According to an example, the first through via TV14 may be formed to penetrate the bonding layer 640 and the second BEOL region 630, and may be in contact with the silicon carrier 650 and the FEOL region 620. According to an example, the second through via TV24 may be formed to penetrate a partial region of the first BEOL region 610. The second through via TV24 may be formed in the first BEOL region 610 and be in contact with a first metal plate 611 of the MIM capacitor Mcap. The temperature control cell 600a may include the first through via TV14 and the second through via TV24, and be utilized as a dissipation path of heat generated in the FEOL region 620. According to an example, the FEOL region 620 of the temperature control cell 600a may further include dummy transistors DTR. According to an example, the dummy transistors DTR may be further included so as to be adjacent to an active device of the temperature control cell 600a functioning as a standard cell, which reduces density in the corresponding cell, thereby effectively suppressing heat generation.

The temperature control cell 600b of FIG. 8B may include a first through via TV15 and a second through via TV25. According to an example, the first through via TV15 may be formed to penetrate a part of each of the bonding layer 640, the second BEOL region 630, and the FEOL region 620. According to an example, the first through via TV15 may be formed to be in contact with the first source/drain region SD1 of the FEOL region 620. According to an example, the second through via TV25 may be formed to penetrate a partial region of the first BEOL region 610. The second through via TV25 may be formed in the first BEOL region 610 and be in contact with the first metal plate 611 of the MIM capacitor Mcap. According to an example, the active devices of the FEOL region 620 included in the temperature control cell 600b may be dummy transistors. No contact may be formed in the first and second gate electrodes G1 and G2 and the first and second source/drain regions SD1 and SD2 included in the FEOL region 620, and the temperature control cell 600b including the dummy transistors may perform temperature control through the first through via TV15 and the second through via TV25 while functioning as a dummy filler cell. In some implementations, one or more metal layers are connected to the first through via TV15 and the second through via TV25 and, as shown in FIGS. 6C and 7C, the first through via TV15 and the second through via TV25 of the temperature control cell 600b, which may be disposed as temperature control filler cells, may be connected to adjacent standard cells through the metal layer to be utilized as a dissipation path of heat generated from the adjacent standard cells.

As described in the implementations of FIGS. 6A to 8B, the temperature control cell may include a first through via, or a second through via, or both the first through via and the second through via, based on a standard cell including a function of a logic circuit. In another example, the temperature control cell may further include dummy transistors, based on the standard cell including the function of the logic circuit. In some implementations, the temperature control cell may include a first through via, or a second through via, or both the first through via and the second through via, based on a filler cell including a dummy function.

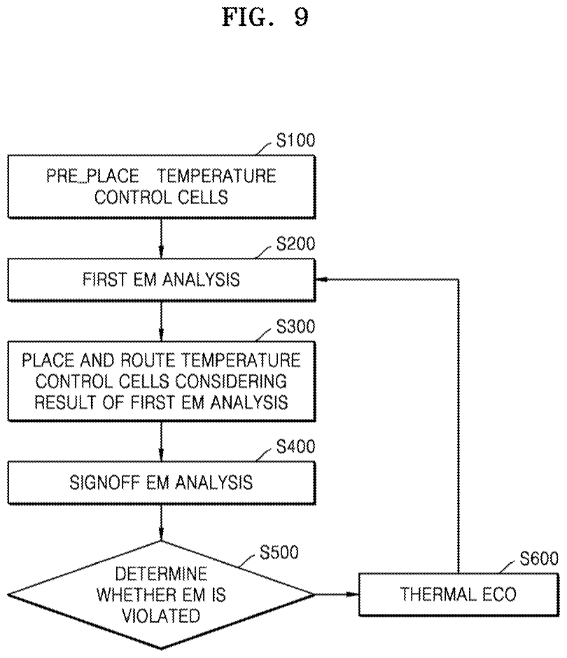

FIG. 9 is a flowchart illustrating a method of placing and routing temperature control cells, according to an implementation.

Referring to operation S100, the temperature control cells may be pre-placed. According to an example, the pre-placed temperature control cells may be temperature control filler cells. According to an example, the temperature control filler cells may be spaced apart from each other at specified positions. According to an example, the pre-placed positions may be positions at which filler cells are determined to be placed. According to another example, the pre-placed positions may be positions at which a lot of switching activity is expected to occur, such as a clock buffer driver.

Referring to operation S200, EM analysis may be first performed based on information included in an integrated circuit. According to an example, the first EM analysis may be performed based on data of a designed semiconductor layout. According to an example, electrical and physical characteristics of a wiring may be defined by inputting a designed layout file (e.g., a graphic design system II (GDSII) or open artwork system interchange standard (OASIS) file) into an EM analysis tool. In this operation, parameters necessary for evaluating reliability of the wiring may be set. According to an example, the first EM analysis may include a process of calculating a current density in the wiring. To this end, the parasitic resistance and capacitance of the wiring may be extracted from the layout, and the current density may be calculated based on the extracted parasitic resistance and capacitance. In this process, the EM analysis tool may be used to determine the maximum current density in the wiring and determine whether the maximum current density exceeds the allowable range by comparing the maximum current density with a design rule check (DRC). According to an example, a region having a high current density may be identified as a region having a high EM violation probability. According to an example, the first EM analysis operation may evaluate the effect of the temperature on EM by calculating a temperature distribution of the wiring. Because the EM risk increases with higher temperature, a heat simulation tool (e.g., ANSYS Workbench) may be used to simulate the heat distribution across the wiring and entire chip. Simulation results may be used to quantitatively evaluate the effect of the temperature rise occurring in a specific region and the resulting current density change on the EM. According to another example, a mean time to failure (MTTF) of the wiring may be predicted using the Black's Equation. Through these various methods, the reliability of the wiring may be evaluated, and EM analysis results may be derived to identify a problem area such as a position where heat above a reference value is generated, a wiring with high current density, and a region where vias are insufficient or overloaded.

In operation S300, the temperature control cells may be placed and routed considering first EM analysis results. According to an example, when a position of the problem area according to the first EM analysis results is a region where the temperature control cells are pre-placed already, standard cells may be placed in the remaining region and routing may be completed without placing additional temperature control cells. According to an example, a metal connection of adjacent standard cells to the through vias of the temperature control filler cells may be additionally performed during the routing process. This may correspond to connection of the metal layer in FIGS. 6C and 7C. According to an example, when the position of the problem area according to the first EM analysis results is spaced apart from the region where the temperature control cells are pre-placed by more than the reference value, additional temperature control cells may be placed, standard cells may be placed in the remaining region, and routing may be completed.

In operation S400, EM analysis may end.

In operation S500, whether EM is violated may be finally confirmed. According to an example, in operation S500, based on layout data on which placing and routing are completed, it may be determined whether the problem of the problem area identified in operation S200 has been solved. According to an example, when it is determined that EM is violated (Y), the design may be modified by generating a thermal engineering change order (ECO) in operation S600. In this process, a design change such as placing temperature control cells may be additionally performed. The modified layout may be re-entered to EM analysis and re-verified. When it is determined that EM is not violated (N), the placement of the temperature control cells may end.

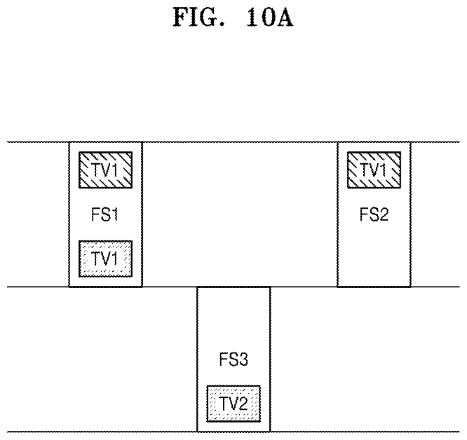

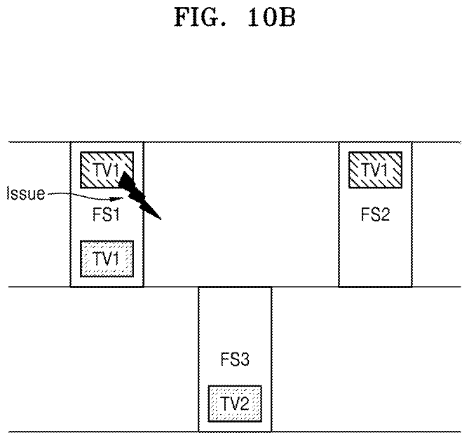

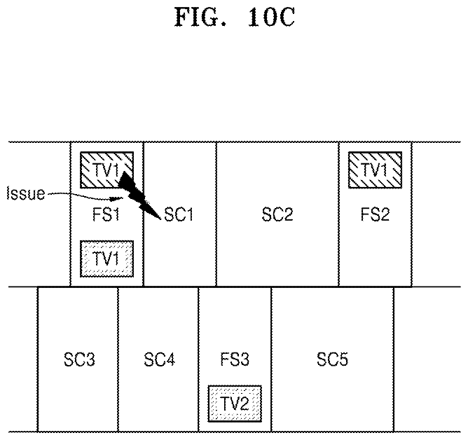

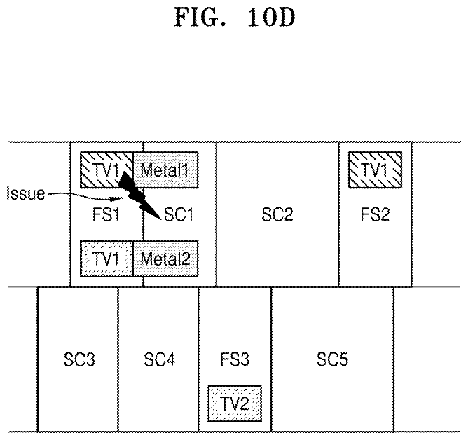

FIGS. 10A to 10D are diagrams for explaining a process of placing and routing first to third temperature control cells FS1, FS2, and FS3 according to an implementation.

Referring to FIG. 10A, an example in which the first to third of temperature control filler cells FS1, FS2, and FS3 are pre-placed is illustrated. For example, FIG. 10A may be a diagram illustrating the first to third temperature control filler cells FS1, FS2, and FS3 are pre-placed according to operation S100 of FIG. 9. According to an implementation, each of the first to third temperature control filler cells FS1, FS2, and FS3 may include at least one through via. According to an example, the first temperature control filler cell FS1 may include the first through via TV1 and the second through via TV2, the second temperature control filler cell FS2 may include the first through via TV1, and the third temperature control filler cell FS3 may include the second through via TV2. In FIG. 10A, an example in which the pre-placed first to third temperature control filler cells FS1, FS2, and FS3 have different structures, that is, through vias included in the first to third temperature control filler cells FS1, FS2, and FS3 have different structures, is illustrated, but this is merely an example, and all of the pre-placed first to third temperature control filler cells FS1, FS2, and FS3 may include the same through via structure.

Referring to FIG. 10B, a first EM analysis may be performed based on the pre-placed first to third temperature control filler cells FS1, FS2, and FS, and a position of a problem area may be identified accordingly. According to an example, the position of the problem area may be identified, and it may be confirmed that the corresponding position is a region overlapping the position of the first temperature control filler cell FS1. According to an example, a result according to FIG. 10B may be a result of completing the first EM analysis according to operation S200 of FIG. 9.

Referring to FIG. 10C, because the first temperature control filler cell FS1 is already placed over the problem area according to the result of performing the first EM analysis, standard cells SC1, SC2, SC3, SC4, and SC5 may be placed in the remaining region without performing additional placement of temperature control cells.

Referring to FIG. 10D, the first through via TV1 and the second through via TV2 of the first temperature control filler cell FS1 placed in the position of the problem area may be connected to the standard cell SC1 adjacent to the first temperature control filler cell FS1 through an additional metal. This may be a configuration corresponding to connection of the metal layer described with reference to FIGS. 6C and 7C. Accordingly, heat generated from the standard cell SC1 placed in the position of the problem area may be directed toward the through via of the first adjacent temperature control filler cell FS1, and thus more effective heat dissipation may be possible. FIGS. 10C to 10D may correspond to an operation of performing placing and routing according to operation S300 of FIG. 9.

According to an example, a method of placing the first to third temperature control cells FS1, FS2, and FS3 of FIGS. 10A to 10D is merely an example, and it should be noted that a specific placing method may be changed according to the position of the problem area and the positions where the first to third temperature control cells FS1, FS2, and FS3 are pre-placed.

According to an example, when the position of the problem area in FIG. 10B is spaced apart from the positions where the first to third temperature control cells FS1, FS2, and FS3 are pre-placed by a certain distance or more, temperature control standard cells may be additionally placed at the position of the problem area or temperature control filler cells may be additionally placed at the position of the problem area.

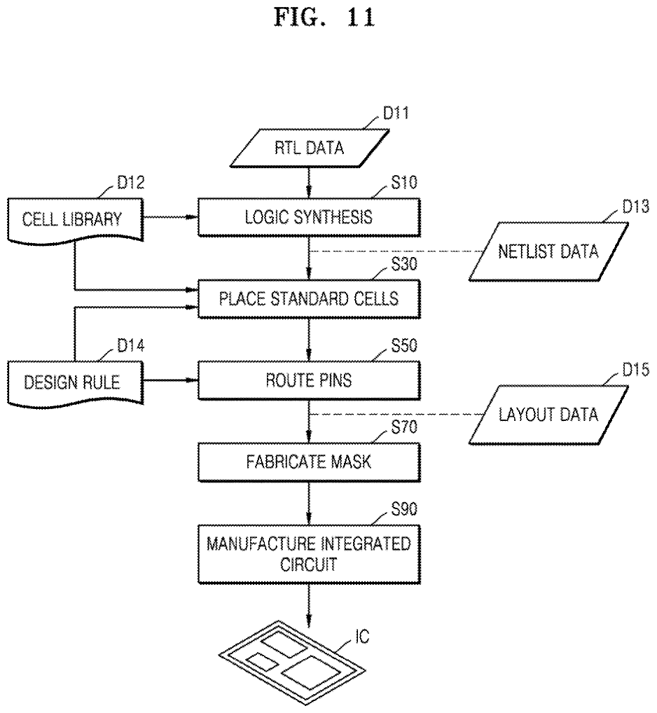

FIG. 11 is a flowchart illustrating a method of manufacturing an integrated circuit IC, according to an implementation.

Referring to FIG. 11, the method according to the implementation, as the method of manufacturing the integrated circuit IC including temperature control cells and standard cells, may include a plurality of operations S10, S30, S50, S70, and S90. A cell library (or a standard cell library) D12 may include information about standard cells, such as information about function, characteristics, layout, etc. In an implementation, the cell library D12 may define tap cells, filler cells, and dummy cells, as well as functional cells that generate output signals from input signals. In an implementation, the cell library D12 may define a plurality of temperature control cells. The design rule D14 may include requirements that the layout of the integrated circuit IC needs to comply with. For example, the design rule D14 may include requirements with respect to spaces between patterns on the same layer, the minimum width of a pattern, a routing direction of a wiring layer, etc. According to an example, the design rule D14 may include a tool and conditions for performing EM analysis according to the present disclosure.

In operation S10, a logic synthesis operation of generating netlist data D13 from RTL data D11 may be performed. For example, a semiconductor design tool (e.g., a logic synthesis tool) may perform logic synthesis by referencing the cell library D12 from the RTL data D11 written in a VHSIC hardware description language (VHDL) and hardware description language (HDL), such as Verilog, and may generate the netlist data D13 including a bitstream or netlist. The netlist data D13 may correspond to input of place and routing described below.

In operation S30, standard cells and temperature control cells may be disposed. For example, a semiconductor design tool (e.g., a P&R tool) may place the standard cells used in the netlist data D13 by referencing the cell library D12. For example, the semiconductor design tool may place the temperature control cells together with the standard cells.

In operation S50, pins of the standard cells may be routed. For example, the semiconductor design tool may generate interconnections that electrically connect output pins to input pins of the placed standard cells and generate layout data D15 defining the placed standard cells and the generated interconnections. The interconnections may include a via of a via layer and/or patterns of wiring layers. The wiring layers may include a front side wiring layer disposed on top of the front side of a substrate and a backside wiring layer disposed on the backside of the substrate. The layout data D15 may have a format, such as GDSII, and may include geometric information of cells and interconnections. The semiconductor design tool may refer to the design rule D14 while routing the pins of cells. The layout data D15 may correspond to output of place and routing. Operation S50 alone or operations S30 and S50 collectively may be referred to as the method of designing an integrated circuit IC.

According to an example, operations S30 and S50 may include operations S100 to S500 in FIG. 9. According to an example, the integrated circuit IC may place and route the temperature control cells to facilitate temperature control in a region where an EM problem occurs through a process of pre-placing the temperature control cells including a first through via and/or a second through via, and redesigning the temperature control cells through EM analysis.

In operation S70, an operation of fabricating a mask may be performed. For example, optical proximity correction (OPC) to correct distortion phenomena, such as refraction caused by the characteristics of light in photolithography, may be applied to the layout data D15. Patterns on the mask may be defined to form patterns disposed on a plurality of layers based on data to which OPC is applied, and at least one mask (or photomask) may be fabricated to form the respective patterns of a plurality of layers. In some implementations, the layout of the integrated circuit IC may be limitedly modified in operation S70, and the limited modification of the integrated circuit IC in operation S70 may be referred to as design polishing as post-processing to optimize the structure of the integrated circuit IC.

In operation S90, an operation of manufacturing the integrated circuit IC may be performed. For example, the integrated circuit IC may be manufactured by patterning a plurality of layers using the at least one mask fabricated in operation S70. An FEOL may include, for example, operations of planarizing a wafer, cleaning the wafer, forming a trench, forming a well, forming a gate line, and forming a source and a drain. By means of the FEOL, individual devices, such as transistors, capacitors, resistors, etc., may be formed on the substrate. In some implementations, a BEOL may include, for example, operations of silicidating gate, source, and drain regions, adding a dielectric, planarizing, forming holes, adding a metal layer, forming a via, forming a passivation layer, etc. By means of the BEOL, individual devices, such as transistors, capacitors, resistors, etc. may be interconnected. In some implementations, a middle-of-line (MOL) may be performed between the FEOL and the BEOL, and contacts may be formed on individual elements. Next, the integrated circuit IC may be packaged into a semiconductor package and used as a component in various applications.

FIGS. 12A to 12D are diagrams illustrating examples of devices according to implementations. For example, FIG. 12A shows a FinFET 1000a, FIG. 12B shows a gate-all-around field effect transistor (GAAFET) 1000b, FIG. 12C shows a multi-bridge channel field effect transistor (MBCFET) 1000c, and FIG. 12D shows a vertical field effect transistor (VFET) 1000d. For convenience of illustration, FIGS. 12A to 12C illustrate that one of two source/drain regions is removed, and FIG. 12D is a cross-sectional view of the VFET 1000d taken along a plane parallel to a plane formed by a Y-axis and a Z-axis and passing through a channel CH of the VFET 1000d. According to an example, the devices shown in FIGS. 12A to 12D may be examples of transistors included in an FEOL region according to the present disclosure.

Referring to FIG. 12A, the FinFET 1000a may be formed by a fin-shaped active pattern extending in the Y-axis direction between shallow trench isolations (STIs) and a gate electrode G extending in the X-axis direction. Source/drain regions SD may be formed on both sides of the gate electrode G, and accordingly, a source and a drain may be spaced apart from each other in the Y-axis direction. An insulating layer may be formed between the channel CH and the gate electrode G. In some implementations, the FinFET 1000a may be formed by a plurality of active patterns spaced apart from each other in the X-axis direction and the gate electrode G, and may have an extended channel.

Referring to FIG. 12B, the GAAFET 1000b may be formed by active patterns spaced apart from each other in the Z-axis direction and extending in the Y-axis direction, that is, nanowires, and the gate electrode G extending in the X-axis direction. The source/drain regions SD may be formed on both sides of the gate electrode G, and accordingly, the source and drain may be spaced apart from each other in the Y-axis direction. An insulating layer may be formed between the channel CH and the gate electrode G. However, the number of nanowires included in the GAAFET 1000b is not limited as shown in FIG. 12B.

Referring to FIG. 12C, the MBCFET 1000c may be formed by active patterns spaced apart from each other in the Z-axis direction and extending in the Y-axis direction, that is, nanosheets, and the gate electrode G extending in the X-axis direction. The source/drain regions SD may be formed on both sides of the gate electrode G, and accordingly, the source and drain may be spaced apart from each other in the Y-axis direction. An insulating layer may be formed between the channel CH and the gate electrode G. It is noted that the number of nanosheets included in the MBCFET 1000c is not limited as shown in FIG. 12C.

Referring to FIG. 12D, the VFET 1000d may include a top source/drain region T_SD and a bottom source/drain region B_SD spaced apart from each other in the Z-axis direction with the channel CH disposed therebetween. The VFET 1000d may include the gate electrode G surrounding the circumference of the channel CH between the top source/drain region T_SD and the bottom source/drain region B_SD. An insulating layer may be formed between the channel CH and the gate electrode G.

According to an example, it is noted that devices included in an integrated circuit are not limited to the examples of FIGS. 12A to 12D. For example, the integrated circuit may include a ForkFET in which N-type transistors and P-type transistors have a closer structure by separating nanosheets for P-type transistors and nanosheets for N-type transistors into dielectric walls. In some implementations, the integrated circuit may include a bipolar junction transistor as well as a FET such as a complementary field effect transistor (CFET), a negative capacitance field effect transistor (NCFET), and a carbon nanotube (CNT) FET.

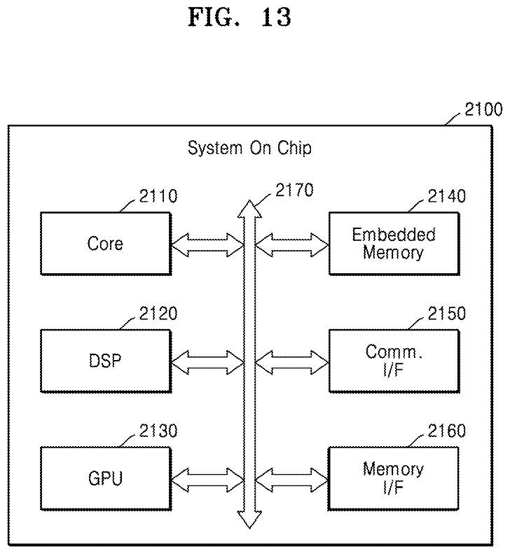

FIG. 13 is a block diagram illustrating a system-on-chip (SoC) 2100 according to an implementation.

Referring to FIG. 13, the SoC 2100 may refer to an integrated circuit that integrates components of a computing system or another electronic system. For example, as an example of the SoC 2100, an application processor (AP) may include a processor and components for other functions. The SoC 2100 may include a core 2110, a digital signal processor (DSP) 2120, a graphics processing unit (GPU) 2130, an embedded memory 2140, a communication interface 2150, and a memory interface 2160.

Components of the SoC 2100 may communicate with each other through a bus 2170.

The core 2110 may process instructions and control the operation of components included in the SoC 2100. For example, the core 2110 may drive an operating system and execute applications on the operating system by processing a series of instructions. The DSP 2120 may generate useful data by processing a digital signal, for example, a digital signal provided from the communication interface 2150. The GPU 2130 may generate data for an image output through a display device from image data provided from the embedded memory 2140 or the memory interface 2160 or may encode the image data. In some implementations, the integrated circuit including temperature control cells described above with reference to the drawings may be included in the core 2110, the DSP 2120, the GPU 2130, and/or the embedded memory 2140. As a result, the integrated circuit including temperature control cells according to the present disclosure is applied to a component generating a lot of heat while consuming a lot of power, thereby securing the SoC 2100 with increased reliability.

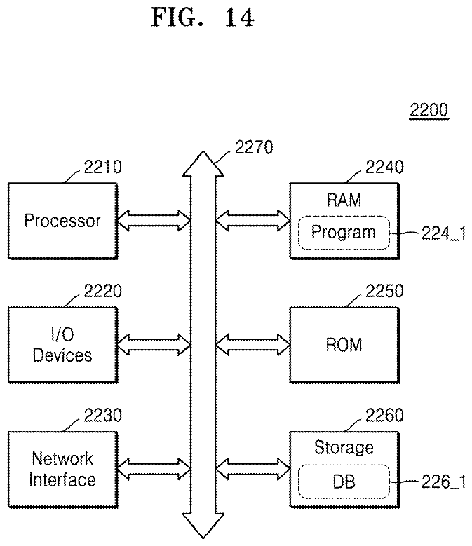

FIG. 14 is a block diagram illustrating a computing system 2200 including a memory storing a program according to an implementation.

Referring to FIG. 14, a method of designing an integrated circuit according to implementations, for example, at least some of the operations of the flowchart described above, may be performed in the computing system 2200 (or a computer). The computing system 2200 may include a processor 2210, I/O devices 2220, a network interface 2230, random access memory (RAM) 2240, read only memory (ROM) 2250, and a storage 2260. The processor 2210, the I/O devices 2220, the network interface 2230, the RAM 2240, the ROM 2250, and the storage 2260 may be connected to a bus 2270 and communicate with each other via the bus 2270.

The processor 2210 may access memory, i.e., the RAM 2240 or the ROM 2250, through the bus 2270 and execute instructions stored in the RAM 2240 or the ROM 2250. The RAM 2240 may store a program 224_1 or at least a part thereof for the method of designing an integrated circuit according to an implementation, and the program 224_1 may cause the processor 2210 to perform the method of designing an integrated circuit, for example, at least some of the operations included in the methods of FIG. 9. That is, the program 224_1 may include a plurality of instructions executable by the processor 2210, and the plurality of instructions included in the program 224_1 may cause the processor 2210 to perform, for example, at least some of the operations included in the flowcharts described above.

The storage 2260 may store the program 224_1 according to an implementation. In some implementations, the storage 2260 may store a database 226_1, and the database 226_1 may include information necessary for designing the integrated circuit, such as information about designed blocks, the cell library D12 and/or design rule D14 of FIG. 11. The storage 2260 may store data to be processed by the processor 2210 or data processed by the processor 2210. For example, the storage 2260 may store the RTL data D11, the netlist data D13 and/or the layout data D15 of FIG. 11.

According to an aspect of the present disclosure, there is provided a method of designing an integrated circuit.

The method includes pre-placing temperature control filler cells, first performing electro migration (EM) analysis according to the pre-placing, placing and routing the temperature control filler cells based on a result of EM analysis, and determining whether EM is violated.

The placing and the routing of the temperature control filler cells based on the result of EM analysis may include additionally placing a temperature control cell when a position of a problem area according to the result of EM analysis is different from positions of the pre-placed temperature control filler cells.

The placing and the routing of the temperature control filler cells based on the result of EM analysis may include connecting vias of the temperature control filler cells to adjacent standard cells through a metal layer when the position of the problem area according to the result of EM analysis is the same as positions of the previously placed temperature control filler cells.

The method may further include additionally placing temperature control cells through a thermal engineering change order (ECO) when it is determined that EM is violated.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been particularly shown and described with reference to implementations thereof, it will be understood that various changes in form and details may be made therein without departing from the spirit and scope of the following claims.

What is claimed is:

1. An integrated circuit comprising a back-side power delivery network (BSPDN), the integrated circuit comprising:
a first back-end-of-line (BEOL) region comprising the BSPDN;
a front-end-of-line (FEOL) region comprising a plurality of transistors;
a second BEOL region comprising signal patterns configured to apply signals to the plurality of transistors;
a bonding layer in contact with a first surface of the second BEOL region; and
wherein the integrated circuit comprises a plurality of cells including a first cell,
wherein the first cell comprises at least one through via connected to the FEOL region.

2. The integrated circuit of claim 1, wherein the at least one through via comprises a first through via extending into the second BEOL region and the bonding layer.

3. The integrated circuit of claim 2, wherein the first through via is in contact with a silicon carrier, wherein the silicon carrier is above the bonding layer.

4. The integrated circuit of claim 2, wherein the first through via is configured to electrically connect to a standard cell, wherein the standard cell is adjacent to the first cell.

5. The integrated circuit of claim 4, wherein the standard cell is at a location identified as a problem area based on a result of electro migration (EM) analysis.

6. The integrated circuit of claim 1, wherein the at least one through via includes a second through via extending into a part of the first BEOL region.

7. The integrated circuit of claim 6, wherein the first BEOL region includes a plurality of metal-insulator-metal (MIM) capacitors.

8. The integrated circuit of claim 7, wherein the second through via is connected to a metal plate of at least one of the plurality of MIM capacitors.

9. The integrated circuit of claim 1, wherein the first cell includes one or more dummy transistors in the FEOL region.

10. The integrated circuit of claim 1, wherein the first cell includes a temperature control filler cell.

11. The integrated circuit of claim 1, wherein the first cell includes a temperature control standard cell.

12. An integrated circuit comprising:
a plurality of standard cells; and
a plurality of filler cells comprising a first cell,
wherein the first cell comprises a through via configured to dissipate heat generated in a front-end-of-line (FEOL) region, and
wherein the through via is in at least one of a first BEOL region below the FEOL region or a second BEOL region above the FEOL region.

13. The integrated circuit of claim 12, wherein the through via extends into an entire depth of the second BEOL region.

14. The integrated circuit of claim 12, wherein the through via extends into only a partial depth of the first BEOL region.

15. The integrated circuit of claim 12, wherein the through via extends into a partial depth of the FEOL region.

16. The integrated circuit of claim 15, wherein the through via is in contact with a transistor included in the FEOL region.

17. An integrated circuit comprising:
a plurality of standard cells comprising a first cell; and
a plurality of filler cells,
wherein the first cell comprises a through via configured to dissipate heat generated in a front-end-of-line (FEOL) region, and
wherein the through via is in at least one of a first BEOL region below the FEOL region or a second BEOL region above the FEOL region.

18. The integrated circuit of claim 17, wherein the through via extends into an entire depth of the second BEOL region.

19. The integrated circuit of claim 17, wherein the through via extends into only a partial depth of the first BEOL region.

20. The integrated circuit of claim 17, wherein the through via extends into a partial depth of the FEOL region.
